(19) United States
(12) Patent Application Publication
(10) Pub. No.: US 2009/0167684 A1
(43) Pub. Date: Jul. 2, 2009

(54) Key Input Apparatus and Method Using Direction-Selector, and Character Input Method Using the Same

(76) Inventors: Jin-Kyeong Kim, Daejon (KR); Woo-Yong Lee, Daejon (KR); Yong-Sun Kim, Deajon (KR); Kyeong-Pyo Kim, Deajon (KR); Hyun Lee, Daejon (KR)

Correspondence Address: STAAS & HALSEY LLP, SUITE 700, 1201 NEW YORK AVENUE, N.W., WASHINGTON, DC, 20005, US

(21) Appl. No.: 12/085,840

(22) PCT Filed: Sep. 29, 2006
(86) PCT No.: PCT/KR2006/003943

§ 371 Date: May 30, 2008

(30) Foreign Application Priority Data
Dec. 1, 2005 (KR) 10-2005-0116073
Apr. 12, 2006 (KR) 10-2006-0033298

(51) Int. Cl. G06F 3/033; H03M 11/00

(52) U.S. Cl. 345/161; 341/22; 345/171

(57) ABSTRACT

Provided are a key input apparatus and method using a direction-selector, and a character input method using the same. The apparatus includes: a direction selection input unit for receiving a direction signal and a selection signal from a user; a storing unit for storing a key value divided by a time and the number of the direction signal and the selection signal; and an operation sensing and determining unit for inquiring the key value divided by the time and the number of the inputted direction signal and selection signal in the storing unit.

### TECHNICAL FIELD

The present invention relates to a key input apparatus and method using a direction-selector, and a character input method using the same; and, more particularly, to a key input apparatus and method using a direction-selector which identifies signals generated from a motion of the direction-selector a direction signal, a continuance signal, and a click signal, and determines a corresponding key value.

Also, the present invention relates to a character input method using the direction-selector which processes a key value inputted by the key input method based on an adopted character input method and provides the result to the user.

### BACKGROUND ART

Generally, a mobile communication terminal may adopt a keypad mounted on the terminal, a touch screen or an individual mobile keyboard to input characters including numbers such as 0 to 9, # and *, English alphabet, Korean alphabet, and other sign characters.

According to the keypad method, a character is inputted by assigning each alphabetic letter in a keypad of the mobile communication terminal and clicking a specific key assigned with a key value.

According to a touch screen, characters are inputted as a user touches a specific region having a keyboard shape displayed on screen.

According to a mobile keyboard, characters are inputted by unfolding a mobile keyboard and connecting the mobile keyboard to the mobile communication terminal by cable or wirelessly, if necessary, while carrying the mobile keyboard with folded.

Since the touch screen is realized on a screen, it cannot reduce a space realized on a liquid crystal display (LCD) screen. On the contrary, the mobile keyboard method has an advantage that it is not affected by a size of a body.

However, the keypad method has a limit in reducing the size of a keypad to easily input characters by clicking keys by a user.

Also, a function for inputting characters is required not by the mobile communication terminal, but by small digital devices such as an MP3 player, a digital camera, and a digital camcorder. However, the keypad capable of inputting characters is not mounted on the small digital devices.

A place where characters need to be inputted but it is not proper to set up the keypad, such as a steering wheel, requires a technology for easily inputting characters without using the keypad.

### DISCLOSURE

### Technical Problem

It is, therefore, an object of the present invention to provide a key input apparatus and method using a direction-selector which identifies signals generated from a motion of the direction-selector as a direction signal, a continuance signal, and a click signal, and determines a corresponding key value.

It is another object of the present invention is to provide a character input method using the key input method which processes a key value based on an adopted character input method and provides the result to the user.

Other objects and advantages of the invention will be understood by the following description and become more apparent from the embodiments in accordance with the present invention, which are set forth hereinafter. It will be also apparent that objects and advantages of the invention can be embodied easily by the means defined in claims and combinations thereof.

### Technical Solution

In accordance with one aspect of the present invention, there is provided a key input apparatus using a direction-selector, the apparatus including: a direction input unit for receiving a direction signal and a selection signal from a user; a storing unit for storing a key value decided by time and number that the direction signal and the selection signal are selected; and an operation sensing and determining unit for inquiring the key value decided by the time and the number that the inputted direction signal and selection signal are selected in the storing unit.

In accordance with another aspect of the present invention, there is provided a key input method using a direction-selector, the method including the steps of: a) receiving a first direction signal or a first selection signal from a direction selection input unit; b) inquiring a key value corresponding to the first direction signal or the second selection signal; and c) outputting a key value based on a inquiry result.

In accordance with another aspect of the present invention, there is provided a character input method using a direction-selector, the method including the steps of: a) a user selecting a character editing function; b) receiving a first direction signal or a first selection signal from a direction input unit in the character editing function; c) inquiring a key value corresponding to the selectively inputted first direction signal or first selection signal; d) outputting the key value based on the inquiry result; and e) when the key value is outputted, processing the key value by the character input method in the middle of driving according to the character editing function and providing the result to the user.

### ADVANTAGEOUS EFFECTS

The present invention can miniaturize a device and create diverse designs by removing a keypad from the device.

Also, the present invention can input a character by using a joystick in small digital devices incapable of inputting a character such as a Personal Digital Assistant (PDA), a digital camera, a digital camcorder, and an MP3 player since a keypad is not mounted.

Although a space is too small to input the character, the present invention can input the character by applying the small space. Also, when the user memorizes a meaning of an operation of the joystick, the user can easily input the character without looking an input device.

### DESCRIPTION OF DRAWINGS

The above and other objects and features of the present invention will become apparent from the following description of the preferred embodiments given in conjunction with the accompanying drawings, in which:

FIG. 1 shows a structure of a direction-selector in accordance with an embodiment of the present invention;

FIG. 2 is a block diagram showing a key input apparatus using the direction-selector in accordance with the embodiment of the present invention;

FIG. 3 shows the direction signal sensed in the operation sensing and determining unit and a key value corresponding to a continuance signal in accordance with the embodiment of the present invention;

FIG. 4 shows number keys of the mobile communication terminal corresponding to key values in accordance with the embodiment of the present invention;

FIG. 5 shows a key value corresponding to the click signal sensed in the operation sensing and determining unit in accordance with the embodiment of the present invention;

FIG. 6 is a block diagram showing the character input device using the key input apparatus in accordance with the embodiment of the present invention;

FIG. 7 shows a result processed in the function processing unit according to the key value determined in the operation sensing and determining unit in accordance with the embodiment of the present invention;

FIG. 8 is a flowchart describing a key input method and a character input method using the same in accordance with an embodiment of the present invention;

FIG. 9 shows character input based on a key input method in accordance with the embodiment of the present invention; and

FIGS. 10 and 11 show examples of the key input apparatus mounted on devices in accordance with the embodiment of the present invention.

### BEST MODE FOR THE INVENTION

Other objects and advantages of the present invention will become apparent from the following description of the embodiments with reference to the accompanying drawings. Therefore, those skilled in the art that the present invention is included can embody the technological concept and scope of the invention easily. In addition, if it is considered that detailed description on related art may obscure the points of the present invention, the detailed description will not be provided herein. The preferred embodiments of the present invention will be described in detail hereinafter with reference to the attached drawings.

A case that a key input apparatus of the present invention is used by being mounted in a mobile communication terminal will be described hereinafter.

Also, diverse input methods such as Cheonjyin developed by Samsung Electronics Co., Ltd., and Narageul developed by LG Electronics Inc., can be used. The present invention will be described based on the Cheonjyin method. Since it can be easily understood by those skilled in the art that the present invention also can be used in other methods by changing the set-up of key values, detailed description will not be provided herein.

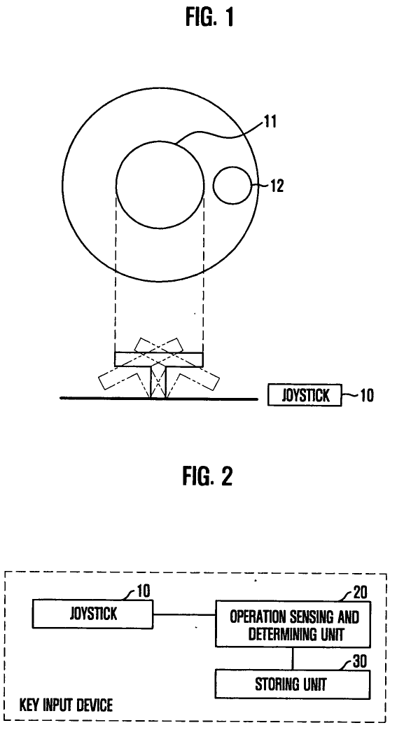

FIG. 1 shows a structure of a direction-selector 10 in accordance with an embodiment of the present invention.

A joystick and a jogdial can be examples of the direction-selector 10. In the present invention, the joystick will be described as an example of the direction-selector 10.

The joystick 10 of the present invention includes a stick 11 and a button 12.

The joystick 10 transforms motion of the stick 11 and the button 12 into signals. In an operation sensing and determining unit, the transformed signals are divided into a direction signal generated when the stick 11 is inclined to an X plane, a click signal generated when the button 12 is clicked, a continuance signal generated when at least one direction signal or click signal is continuously inputted within a pre-set time. In the present invention, “continuance” means to be operated within a pre-set time.

Motion by the stick 11 and the button 12 will be called motion of the joystick 10 hereinafter for the sake of convenience in explanation.

In addition, the joystick 10 can be used by attaching the button 12 to the stick 11. In the joystick 10, the button 12 is clicked and a click signal is inputted not when a direction signal of the stick 11 is inputted, i.e., when the stick 11 is inclined, but when the button 12 stands vertically to the X plane.

FIG. 2 is a block diagram showing a key input apparatus using the direction-selector 10 in accordance with the embodiment of the present invention.

The key input apparatus of the present invention includes the joystick 10, the operation sensing and determining unit 20, and a storing unit 30.

When a motion of the joystick 10 by a user is transformed into a signal, the key input apparatus of the present invention identifies the transformed signal and determines a key value corresponding to the direction signal, the continuance signal, and the click signal. The key input apparatus inputs the determined key value in a place for processing the key value, i.e., a function processing unit, according to a character input method adopted by the character input device. Subsequently, the function processing unit processes the inputted key value and provides the result to the user.

The joystick 10 substitutes for a keypad of the mobile communication terminal. That is, the joystick 10 transforms the motion inputted by the user into the signal.

The storing unit 30 stores key values corresponding to the direction signal, the continuance signal and the click signal in a table.

The operation sensing and determining unit 20 identifies whether the signal sensed by the joystick 10 is the direction signal, the continuance signal or the click signal.

The operation sensing and determining unit 20 inquires and determines which key value stored in the storing unit 30 the identified signals correspond to. Subsequently, the operation sensing and determining unit 20 transmits the determined key value to the function processing unit.

Hereinafter, it is assumed that the signal sensed by the joystick 10 is identified as the direction signal, the continuance signal, or the click signal in the operation sensing and determining unit 20.

In addition, the key input apparatus transforms the motion inputted through touch screen by the user into a signal, identifies the transformed signal and determines a key value corresponding to the direction signal, the continuance signal, and the click signal.

When a hand of a human being or a thing touches a specific location on screen, the touch screen grasps the location and directly receives present data on screen by running stored software. The touch screen can receive the direction signal, the continuance signal, and the click signal as receiving a motion by using the joystick 10 on screen, and determines the key value corresponding to the signal.

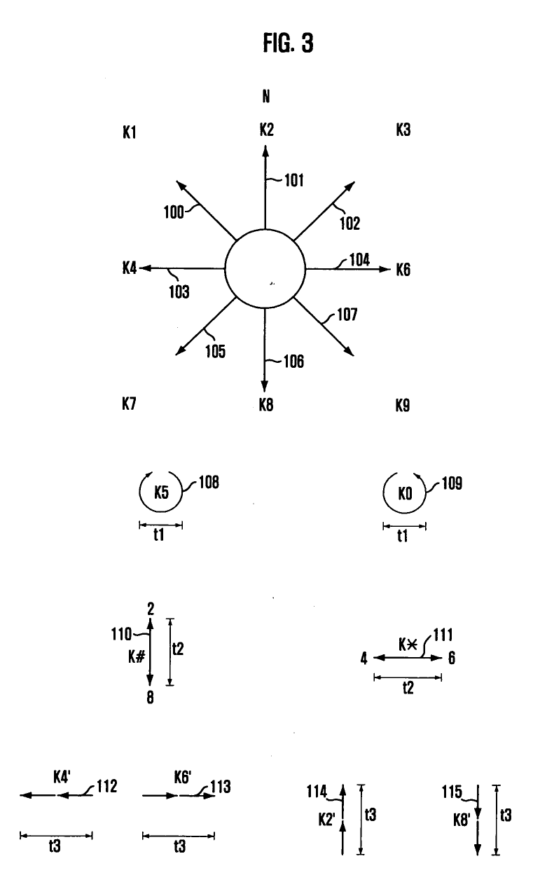

FIG. 3 shows the direction signal sensed in the operation sensing and determining unit 20 and a key value corresponding to the continuance signal in accordance with an embodiment of the present invention.

The direction signal is expressed based on a direction designated by each number around a number 5, which is a number key on a keypad, for the sake of convenience in explanation. Herein, a direction of a number 2 is the north. When it is difficult to express only by the direction signal, numbers “0” and “5”, special characters “*” and “#”, and the direction signal of continuous two-times are expressed as the continuance signal.

Referring to FIG. 3, the key value corresponding to the direction signal is as Table 1.

TABLE 1

| Direction signal | Key Value |
|---|---|
| Northwest 100 | K1 |
| North 101 | K2 |
| Northeast 102 | K3 |
| West 103 | K4 |
| East 104 | K6 |
| Southwest 105 | K7 |
| South 106 | K8 |
| Southeast 107 | K9 |

Referring to FIG. 3 and the Table 1, the operation sensing and determining unit 20 senses a direction signal by the joystick 10 and determines a corresponding key value. For example, when the operation sensing and determining unit 20 senses a direction signal of a northwest 100 inputted once, the key value is determined as “K1”. The operation sensing and determining unit 20 can determine the key value corresponding to the direction signal of each direction sensed by the joystick 10.

Referring to FIG. 3, the continuance signal and the corresponding key value are as shown in Table 2. The continuance signal should be operated within a time, which is pre-set as a default value and a set time of each continuance signal is as shown in the Table 2. In addition, the set time can be re-established by the user.

TABLE 2

| Continuance signal | Set Time | Key Value |
|---|---|---|
| Clockwise Rotation 108 | t1 | K5 |
| Counter-clockwise rotation | t1 | K0 |
| 109 | | |
| North-south [or south-north] | t2 | K# |
| 110 | | |
| East-west [or West-east] 111 | t2 | K* |
| Continuous double motion to | t3 | K4′ |
| West 112 | | |
| Continuous double motion to | t3 | K6′ |
| East 113 | | |
| Continuous double motion to | t3 | K2′ |
| North 114 | | |
| Continuous double motion to | t3 | K8′ |
| South 115 | | |

Referring to FIG. 3 and Table 2, when the operation sensing and determining unit 20 senses the continuance signal that at least one direction signal or click signal is sensed within a set time in the joystick 10, the operation sensing and determining unit 20 combines key values of each signal organizing the continuance signal and inquires a corresponding key value.

For example, when the operation sensing and determining unit 20 senses the direction signal of the north 101 once and the direction signal of the south 106 once within a set time, the operation sensing and determining unit 20 determines the direction signals not as each key value, i.e., “K2” and “K8”, but as “K#” corresponding to a value combining “K2” and “K8”. When it is sensed that the continuance signal exceeds the set time, the operation sensing and determining unit 20 determines the continuance signals as each key value, i.e., “K2” and “K8”.

Since a character assigned to the key value, i.e., a number, Korean alphabetic letters, and English alphabet is assigned as well-known “Cheonjyin” method in the present invention, detailed description will not be provided hereinafter. As an example, a number 4, Korean consonant [symbol] and English alphabet “G” are assigned to the key value “K4”.

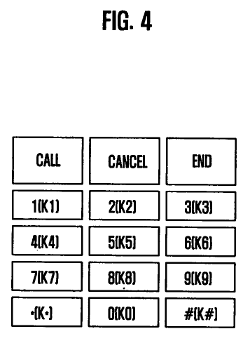

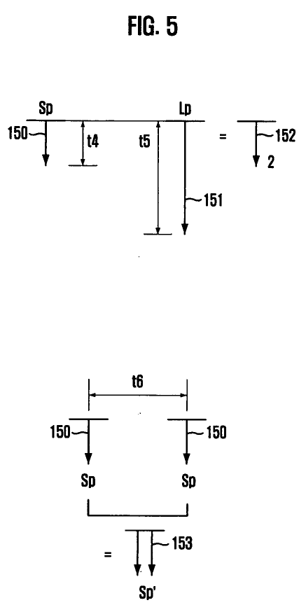

FIG. 4 shows number keys of the mobile communication terminal corresponding to key values in accordance with an embodiment of the present invention.

The key value determined in the operation sensing and determining unit 20 by using the joystick 10 in the present invention corresponds to the key value corresponding to the number key on a mobile communication terminal keypad.

In the present invention, when the joystick 10 instead of the keypad is mounted and used in the mobile communication terminal, the key value corresponding to the number key on the mobile communication terminal keypad becomes the key value determined in the operation sensing and determining unit 20 by using the joystick 10. Accordingly, the function processing unit receives the key value by using a joystick and processes a character editing function as the key value of the number key is inputted by using the keypad.

FIG. 5 shows a key value corresponding to the click signal sensed in the operation sensing and determining unit 20 in accordance with an embodiment of the present invention.

The click signal is expressed according to a continuous click time and the click number of the joystick 10. That is, when the continuous click time is “t4”, the click signal is called “a short click signal 150”. When the continuous click time is “t5”, the click signal is called “a long click signal 151 or 152”. When a button is clicked once within a “t6” time, the click signal is called “the one-time short click 150”. When a button is clicked twice within the “t6” time, the click signal is called “double motion as a short click 153”.

The long click signal is displayed as 152 and the short click of double input is displayed as 153 for the sake of convenience in explanation.

To clearly discern t4 and t5, it is preferred to discern the short click signal and the long click signal by setting up the t5 as t5≧t4×2, which means two times longer than t4. Also, t4 to t6 are the time which is previously set up as default values and they can be adjusted by the user.

The click signal and the corresponding key value are as shown in Table 3. Although the short click 153 is inputted twice continuously, it will be described in Table 3.

TABLE 3

| Click Signal | Key Value |
|---|---|
| Short click signal 150 | Sp |
| Long click signals 151 and 152 | Lp |
| One-time short click 150 | Sp |
| Double input of Short click 153 | Sp′ |

Referring to FIG. 5 and Table 3, when a click signal is sensed, the operation sensing and determining unit 20 determines the corresponding key value. That is, when a short click signal is sensed, the operation sensing and determining unit 20 determines the key value as “Sp”. The operation sensing and determining unit 20 determines the key value as “Lp” in case of the long click signal, “Sp” in case of the one-time short click signal and “Sp′” in case of two-time short click signal.

As described above, the key values corresponding to the signals of FIGS. 3 and 5 are stored as a table in the storing unit 30 as shown in Tables 1 to 3.

Therefore, the operation sensing and determining unit 20 searches and determines a key value corresponding to the signal sensed in the joystick 10 in the storing unit 30.

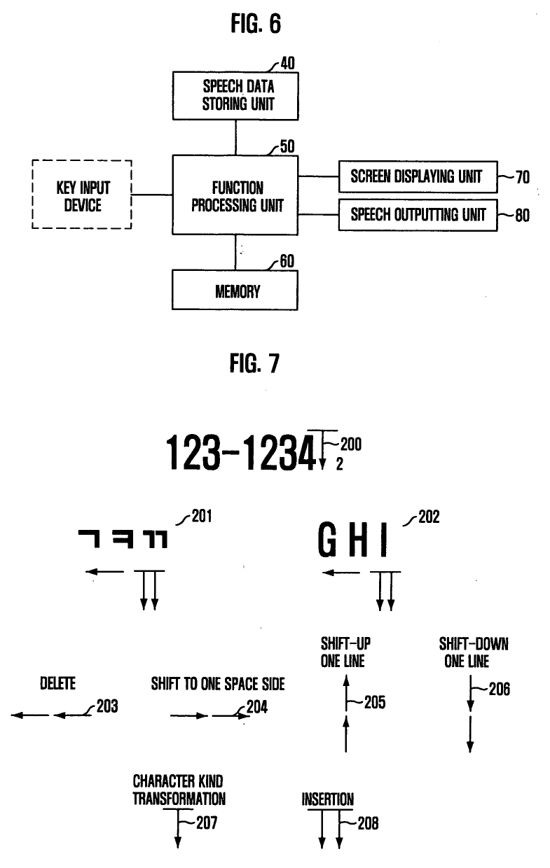

FIG. 6 is a block diagram showing the character input device using the key input apparatus in accordance with an embodiment of the present invention.

The character input device using the key input apparatus includes a speech data storing unit 40, a function processing unit 50, a memory 60, a screen displaying unit 70 and a speech output unit 80.

The memory 60 loads an application realized by the character input method adopted in the character input device, e.g., Cheonjyin in the present invention and Naramal, and provides the application upon request of the function processing unit 50.

The function processing unit 50, which is Central Processing Unit (CPU) or Micro Processor Unit (MPU), controls the character input device and receives a key value from the key input apparatus, i.e., the operation sensing and determining unit 20.

Also, the function processing unit 50 processes the inputted key value in real-time and displays a character through the screen displaying unit 70 or/and the speech output unit 80. The function processing unit 50 drives the application stored in the memory 60 to process the key value based on the adopted character input method.

When the key value processed in the function processing unit 50 is outputted as speech through the speech output unit 80, the speech data storing unit 40 stores speech data corresponding to each character.

The key value processed by the function processing unit 50 is displayed in the screen displaying unit 70 and the speech output unit 80. That is, in the screen displaying unit 70, the key value processed by the function processing unit 50 is displayed on screen such as a liquid crystal display (LCD) screen. In the speech output unit 80, the key value processed by the function processing unit 50 is outputted as speech through a speaker based on the speech data stored in the speech data storing unit 40.

In addition, when an input mode is English, the speech output unit 80 outputs a corresponding alphabet as speech whenever each alphabet, i.e., the processed key value, is updated. When the input mode is Korean, the speech output unit 50 outputs corresponding alphabetic letters as speech whenever each alphabetic letter is updated, and outputs a finally completed Korean character as speech.

FIG. 7 shows a result processed in the function processing unit 50 according to the key value determined in the operation sensing and determining unit 20 in accordance with an embodiment of the present invention.

Generally, there are a dialing mode, i.e., a status when the mobile communication terminal is open, and a character editing mode, i.e., writing a message and address writing. Accordingly, the function processing unit 50 processes the key value transmitted from the operation sensing and determining unit 20.

In the dialing mode, a procedure for processing a call with a phone number “123-1234” respectively performed in the operation sensing and determining unit 20 and the function processing unit 50 is described at 200.

When the direction signal is sensed once in a northwest 100, once in a north 101, once in a northeast 102, once in a west 103 in the joystick 10, the operation sensing and determining unit 20 determines key values corresponding to the direction signals as “K1, K2, K3, K1, K2, K3 and K4”. Subsequently, when the long click signal from the joystick 10 is sensed, the operation sensing and determining unit 20 determines a key value as “Lp”.

When the key value determined in the operation sensing and determining unit 20 is inputted to the function processing unit 50, the function processing unit 50 processes the key value as calling to a phone number “123-1234”.

In the character editing mode, a procedure that a Korean consonant [symbol] i.e., an English alphabet “I”, is respectively performed in the operation sensing and determining unit 20 and the function processing unit 50 will be described at 201 and 202.

When the direction signal from the joystick 10 is sensed as the west 103, the operation sensing and determining unit 20 determines a key value as “K4”. Subsequently, when the short click from the joystick 10 is sensed twice continuously, the operation sensing and determining unit 20 determines a key value as “Sp′”.

As describe above, when the key value determined in the operation sensing and determining unit 20 is inputted to the function processing unit 50, the function processing unit 50 processes the key value as the Korean consonant [symbol] the English alphabet, i.e., “I”, through a Korean consonant [symbol] , i.e., an English alphabet “I”, and a Korean consonant [symbol] , i.e., an English alphabet “H”.

In the character editing mode, each procedure for processing \textcircled{1} delete/\textcircled{2} shift to one space side/\textcircled{3} shift-up one line/\textcircled{4} shift-down one line respectively performed in the operation sensing and determining unit 20 and the function processing unit 50 will be described at 203 to 206.

When the direction signal from the joystick 10 is sensed as \textcircled{1} double motion to the west 103, the operation sensing and determining unit 20 determines a key value as “K4′”. The operation sensing and determining unit 20 determines a key value as “K6′” in case of \textcircled{2} double motion to the east 104, “K2′” in case of \textcircled{3} double motion to the north 101 and “K8′” in case of \textcircled{4} double motion to the south 106.

As described above, when the key values determined in the operation sensing and determining unit 20 are inputted to the function processing unit 50, the function processing unit 50 processes each key value as \textcircled{1} delete/\textcircled{2} shift to one space side/\textcircled{3} shift-up one line/\textcircled{4} shift-down one line.

In the character editing mode, each procedure for processing \textcircled{1} a character kind transforming mode, i.e., a state in which kinds of characters can be selected/\textcircled{2} insertion respectively performed in the operation sensing and determining unit 20 and the function processing unit 50 will be described at 207 and 208.

The operation sensing and determining unit 20 determines key values as “Sp” in case of \textcircled{1} one-time short click and “Sp′” in case of \textcircled{2} double motion as short click with respect to the click signal without the direction signal from the joystick 10.

When the key values determined in the operation sensing and determining unit 20 are inputted in the function processing unit 50, the function processing unit 50 processes each key value as \textcircled{1} the character kind transforming mode/\textcircled{2} insertion.

In addition, when the character kind transforming mode is processed in the function processing unit 50, the kind of the character is sequentially changed whenever the key value of the short click of one-time is inputted. That is, the kind of the character is changed into an English mode by the one-time short click in the first Korean input mode, and changed again into a number mode by the short click of one-time.

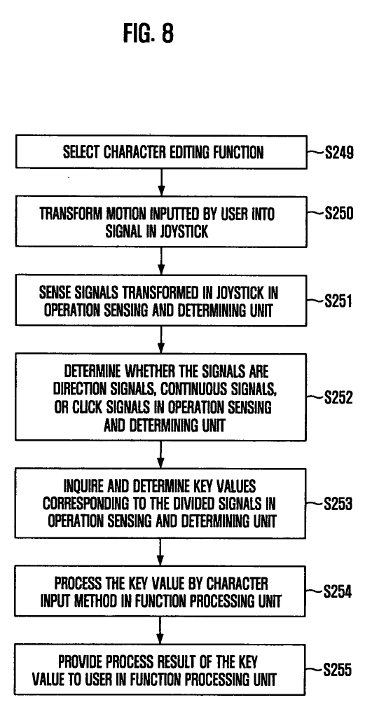

FIG. 8 is a flowchart describing a key input method and a character input method using the same in accordance with an embodiment of the present invention.

At step S249, a user selects a character editing function in the function processing unit 50.

At step S250, the joystick 10 transforms a motion inputted by the user into a signal.

At step S251, the operation sensing and determining unit 20 senses the signal transformed in the joystick 10. At step S252, the operation sensing and determining unit 20 determines whether the signal is the direction signal, the continuance signal, or the click signal.

As described above, the operation sensing and determining unit 20 senses the signal as the direction signal according to a signal corresponding to the direction, as the continuance signal based on whether at least one direction signal or click signal is continuously inputted within a pre-determined time, and as the click signal according to a continuous click time and the number of click.

At step S253, the operation sensing and determining unit 20 inquires and determines key values corresponding to the divided signals based on the table stored in the storing unit 30.

The operation sensing and determining unit 20 inputs the determined key value in the function processing unit 50. At step S254, the function processing unit 50 processes the key value by the character input method in the middle of driving, i.e., an application.

At step S255, the function processing unit 50 provides a process result of the key value to the user in real-time. The function processing unit 50 provides the process result of the key value based on the screen displaying unit 70 and/or the speech output unit 80.

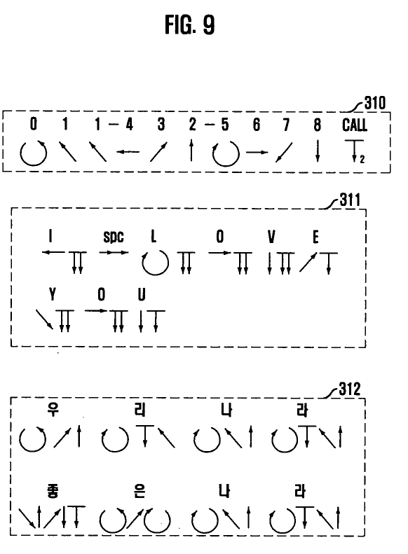

FIG. 9 shows character input based on a key input method in accordance with an embodiment of the present invention.

A character inputted by the joystick 10 is outputted as follows.

The number inputted by the joystick 10 is outputted as a phone number “011-432-5678” at 310.

The alphabet inputted by the joystick 10 is outputted as “I LOVE YOU” in English at 311.

Alphabetic letters inputted by the joystick 10 are outputted as [symbol] in Korean at 312.

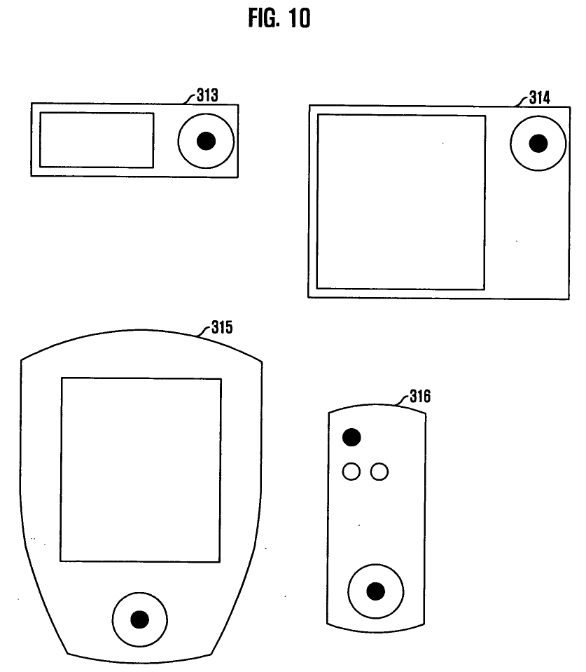

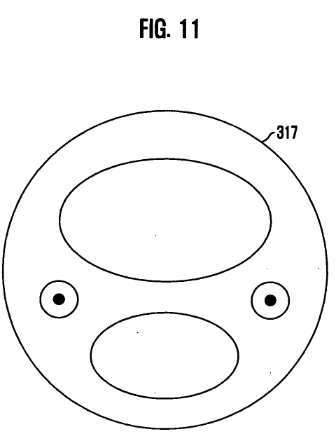

FIGS. 10 and 11 show a case mounting the key input apparatus, to which the present invention is applied.

As shown in FIG. 10, the key input apparatus of the present invention is applied to not only the mobile communication terminal, but applied to most small digital devices including an MP3 player 313, a digital camera 314, a Personal Data Assistant (PDA) 315, and a remote controller 316. Accordingly, the user can easily input the character, if necessary.

As shown in FIG. 11, the key input apparatus of the present invention can be applied to a steering wheel 317. For example, when the user should input characters without looking at the input device, i.e., when the driver should input the characters in a state that a number key cannot be checked while driving, the driver can easily input the characters through the joystick mounted on the steering wheel 317 under assumption that the driver memorizes a meaning of an operation of the joystick 10.

As described above, the technology of the present invention can be realized as a program and stored in a computer-readable recording medium, such as CD-ROM, RAM, ROM, a floppy disk, a hard disk and a magneto-optical disk. Since the process can be easily implemented by those skilled in the art, further description will not be provided herein.

The present application contains subject matter related to Korean patent application Nos. 2005-0116073 and 2006-0033298 filed with the Korean Intellectual Property Office on Dec. 1, 2005, and Apr. 12, 2006, respectively, the entire contents of which are incorporated herein by reference.

While the present invention has been described with respect to certain preferred embodiments, it will be apparent to those skilled in the art that various changes and modifications may be made without departing from the scope of the invention as defined in the following claims.

1. A key input apparatus using a direction-selector, comprising:
a direction input means for receiving a direction signal and a selection signal from a user;
a storing means for storing a key value decided by time and number that the direction signal and the selection signal are selected; and
an operation sensing and determining means for inquiring the key value decided by the time and the number that the inputted direction signal and selection signal are selected in the storing means.

2. The apparatus as recited in claim 1, wherein when at least one direction signal or selection signal is continuously inputted within a predetermined set time, the operation sensing and determining means determines the signal as the continuance signal and inquires a key value corresponding to the continuance signal in the storing means.

3. The apparatus as recited in claim 2, wherein the operation sensing and determining means provides the predetermined set time to the user to change the predetermined set time.

4. The apparatus as recited in claim 2, wherein the storing means stores the key value decided by the direction signal, the selection signal and the continuance signal in a table.

5. The apparatus as recited in claim 1, wherein when the operation sensing and determining means decides a selection signal according to a click time of the direction input means, a long click time is set up to be two times longer than a short click time.

6. A key input method using a direction-selector, comprising:
receiving a first direction signal or a first selection signal from a direction input means;
inquiring a key value corresponding to the first direction signal or the second selection signal; and
outputting a key value based on a inquiry result.

7. The method as recited in claim 6, wherein the inquiring a key value corresponding to the first direction signal or the second selection signal includes:
when a second direction signal or a second selection signal is inputted within a predetermined set time after the first direction signal or the first selection signal is inputted, inquiring a key value corresponding to a value combining the continuously inputted direction signals or selection signals; and
when the predetermined set time ends after the first direction signal or the first selection signal is inputted, inquiring a key value corresponding to the first direction signal or the first selection signal.

8. The method as recited in claim 7, wherein the predetermined set time can be changed by the user.

9. The method as recited in claim 7, wherein when a click time of the first selection signal is longer than a click time of the second selection signal, the click time of the first selection signal is two times longer than the click time of the second selection signal.

10. A character input method using a direction-selector, comprising:
a user selecting a character editing function;
receiving a first direction signal or a first selection signal from a direction input means in the character editing function;
inquiring a key value corresponding to the selectively inputted first direction signal or first selection signal;
outputting the key value based on the inquiry result; and
when the key value is outputted, processing the key value by the character input method in the middle of driving according to the character editing function and providing the result to the user.

11. The method as recited in claim 10, wherein the inquiring a key value corresponding to the selectively inputted first direction signal or first selection signal includes:
when a second direction signal or a second selection signal is inputted within a predetermined set time after the first direction signal or the first selection signal is inputted, inquiring a key value corresponding to a value combining the continuously inputted direction signals or selection signals; and
when the predetermined set time ends after the first direction signal or the first selection signal is inputted, inquiring a key value corresponding to the first direction signal or the first selection signal.

12. The method as recited in claim 10, wherein the process result of the key value is outputted as speech and provided to the user.

13. The method as recited in claim 12, wherein when an input mode is English, the process result of the key value is outputted as speech whenever the key value is updated.

14. The method as recited in claim 12, wherein when an input mode is Korean, a corresponding key value that forms a Korean character is outputted as speech whenever the key value is updated, and when the Korean character is completed, the Korean character is outputted as speech.
